(19) United States
(12) Patent Application Publication
(10) Pub. No.: US 2025/0266281 A1
(43) Pub. Date: Aug. 21, 2025

(54) ELECTROSTATIC WAFER CLAMPING AND SENSING SYSTEM

(71) Applicant: Advanced Energy Industries, Inc., Denver, CO (US)

(72) Inventor: Donnie W. Herman, Olcott, NY (US)

(21) Appl. No.: 18/442,876

(22) Filed: Feb. 15, 2024

(51) Int. Cl. H01L 21/683; H01J 37/32

(52) U.S. Cl. CPC H01L 21/6833; H01J 37/32715; H01J 37/32926; H01J 37/3299; H01J 2237/24564; H01J 2237/24571

(57) ABSTRACT

An electrostatic wafer clamping and sensing system includes a power source configured to provide a high voltage clamping signal. A transformer, having a primary and a secondary, is coupled in series with an output of the power source. An AC voltage source is coupled to the primary of the transformer and operates at a frequency within the bandpass of a filter of a plasma processing chamber. A voltage sensing circuit is coupled to an opposing end of the primary of the transformer, the two ends being separated by a center tap. The high voltage clamping signal and a capacitance sensing AC signal from the AC voltage source are combined via the secondary and passed to a capacitive load. While the AC voltage source is held constant, amplitude modulation at the voltage sensing circuit indicates a clamping state of an electrostatic chuck.

### BACKGROUND

### Field

The present disclosure relates generally to monitoring electrical elements, and more particularly, to monitoring capacitance.

### Background

Electrostatic chucks are widely used in various processing systems to support workpieces, such as wafers. These chucks utilize electrostatic force to hold the workpiece in place. The electrostatic chuck includes electrodes that are energized with a clamping voltage, which electrostatically clamps the workpiece to the surface of the electrostatic chuck. The electrodes in the electrostatic chuck are coupled to an electrostatic power supply and a controller. The electrostatic power supply receives a control signal from the controller and generates a clamping voltage adapted to clamp the substrate with a clamping force.

Monitoring the position of the workpiece relative to the electrostatic chuck is of utmost relevance at various stages of the workpiece processes. For instance, it is imperative to ensure that a workpiece is properly loaded onto the electrostatic chuck before applying the clamping voltage. Furthermore, it may be desirable to determine whether the workpiece is clamped or unclamped at specific times.

The position of the workpiece can be detected by monitoring the capacitance of a combination of the workpiece and the electrostatic chuck. For example, when the workpiece is properly positioned on the electrostatic chuck, the sensed capacitance may be higher than when the workpiece is not properly positioned. The varying level of current provided to the electrostatic chuck, in response to the application of an alternating current (AC) voltage, enables the capacitance of the electrostatic chuck to be monitored. Consequently, the position of the workpiece may be monitored by monitoring the current provided to the electrostatic chuck.

However, the presence of low pass filters (e.g., RLC) on plasma processing chambers can render inoperable known capacitive sensing systems for wafer clamping as these filters largely block the high frequency and low amplitude sensing signals used to perform capacitance sensing of substrate position on the electrostatic chuck. Furthermore, capacitance sensing circuits are often built into custom power supplies or amplifiers, whereas there is a desire to add capacitance sensing as an add-on module to existing off-the-shelf power supplies or amplifiers.

### SUMMARY

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

The present disclosure generally relates to an electrostatic wafer clamping and sensing system. The system includes a voltage or current source, an output configured for coupling to an electrode of an electrostatic chuck, and an electrical connection between the voltage or current source and the output. The electrostatic chuck may include a low pass filter between the output and the electrode.

The system also includes a wafer chucking sense circuit. The wafer chucking sense circuit is inductively coupled to the electrical connection and comprises a transformer having a primary and a secondary. The secondary of the transformer is coupled in series with the electrical connection. An AC voltage source is coupled to the primary of the transformer, and a voltage sensing circuit is coupled to an opposing end of the primary of the transformer.

The AC voltage source is configured to operate within the bandpass of the low pass filter. This operation within the bandpass of the low pass filter allows a substantial portion of the capacitance sense signal to reach the electrostatic chuck, thereby enabling effective monitoring of the position of the workpiece. In some cases, the AC voltage source is configured to operate at a frequency of 5 or 50 Hz. This low frequency operation further enhances the ability of the capacitance sense signal to pass through the low pass filter and reach the electrostatic chuck.

Amplitude modulation at the voltage sensing circuit indicates a clamping state of the electrostatic chuck. This allows for real-time monitoring of the clamping state, thereby enhancing the overall control over the workpiece processes. The use of a tapped connection in a middle of the primary provides signal separation between the time-varying signal inductively coupled into the secondary and the sensed signal coupled back into the output side of the primary. This, along with a capacitance sense signal tailored to a passband of a filter of the capacitive load, allows the system to perform both clamping and monitor workpiece clamping despite the existence of a low pass filter upstream from the electrostatic chuck or other load.

In general, in a first aspect, the system features an electrostatic wafer clamping and sensing system. This system includes a power source configured to provide a high voltage clamping signal. The system also includes a transformer having a primary and a secondary, with the secondary coupled in series with an output of the power source. An AC voltage source is coupled to the primary of the transformer, and is configured to operate at a frequency within the bandpass of a low pass filter of a plasma processing chamber. A voltage sensing circuit is coupled to an opposing end of the primary of the transformer. The high voltage clamping signal and a low frequency capacitance sensing AC signal from the AC voltage source are combined and passed to a load. Amplitude modulation at the voltage sensing circuit indicates a clamping state of an electrostatic chuck. Embodiments of the system may include one or more of the following features. The primary of the transformer may include a tapped connection (e.g., ground or common to the reference of the AC voltage source). The AC voltage source may be configured to operate at a frequency of 5 to 50 Hz. The power source may be configured to turn on and off as substrates are clamped and declamped. The system may further include a resistive device, wherein the amplitude modulated capacitance sense signal has a voltage equal to the voltage drop across the resistive device. The high voltage output of the power supply or amplifier may include an AC shunt to ground between the output and the secondary of the high-voltage transformer. The secondary of the transformer may have fewer turns than a number of turns in the primary. The secondary of the transformer may be a single conductor passing through a toroidal primary. The system may be arranged external to the power source, or it may be part of the power source.

In some aspects, the techniques described herein relate to a system, including: a power source configured to provide a voltage to a node; a transformer having a primary and a secondary, the secondary coupled to the power source and to the node, the primary comprising a tap; a time-varying source coupled to the primary of the transformer on a first side of the tap; and a sensing circuit coupled to the primary of the transformer on a second side of the tap, and configured to measure a time-varying amplitude on the second side of the tap. This time-varying amplitude can be indicative of a capacitance at the node.

In some aspects, the techniques described herein relate to an apparatus, including: a power source configured to provide a voltage; a transformer having a primary and a secondary, the secondary coupled to an output of the power source; a time-varying source coupled to the primary of the transformer and configured to inject a time-varying signal onto a conduction path between the power source and a node; and a monitor configured to measure time-varying amplitude in the conduction path via a portion of the primary.

In some aspects, the techniques described herein relate to a non-transitory, tangible computer-readable storage medium storing instructions that, when executed by a processor, cause a system to perform operations, including: providing a clamping voltage; providing a time-varying voltage; and detecting amplitude modulation of a combined signal that results from the time-varying voltage being inductively coupled to the clamping voltage.

### BRIEF DESCRIPTION OF THE DRAWINGS

FIG. 1 illustrates an exemplary electrostatic chucking system with an exemplary electrostatic power supply having a time-varying source, in accordance with one or more embodiments.

FIG. 2 is a block diagram of an electrostatic power supply using amplitude modulated capacitance sensing.

FIG. 3 provides additional details of the amplitude modulated capacitance sensing.

FIG. 4 presents additional details of an amplitude modulation sensing circuit.

FIG. 5 is a block diagram of electrostatic power supply using amplitude modulated capacitance sensing with a bypass circuit.

FIG. 6 depicts a method of monitoring a capacitive load via an amplitude modulated capacitive sensing signal.

FIG. 7 is an exemplary block diagram depicting physical processing related components that may be used to realize aspects described herein.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

Disclosed herein are multiple approaches to monitoring capacitance. Although several aspects disclosed herein are separately described, they are not mutually exclusive, and instead, these aspects may be combined in multiple variations to provide improved capacitance sensing. Although the capacitance sensing techniques are described throughout this specification in the context of electrostatic chucking systems, it should be recognized that many of the capacitance-sensing approaches disclosed herein are applicable in other contexts where capacitance sensing is useful.

The system can be used in various processing systems to support workpieces, such as wafers. These systems utilize electrostatic force to hold the workpiece in place. The electrostatic chuck includes electrodes that are energized with a clamping voltage, which electrostatically clamps the workpiece to the surface of the electrostatic chuck. The electrodes in the electrostatic chuck are coupled to an electrostatic power supply and a controller. The electrostatic power supply receives a control signal from the controller and generates a clamping voltage adapted to clamp the substrate with a clamping force.

Monitoring the position of the workpiece relative to the electrostatic chuck is of utmost relevance at various stages of the workpiece processes. For instance, it is imperative to ensure that a workpiece is properly loaded onto the electrostatic chuck before applying the clamping voltage. Furthermore, it may be desirable to determine whether the workpiece is clamped or unclamped at specific times.

The position of the workpiece can be detected by monitoring the capacitance of a combination of the workpiece and the electrostatic chuck. For example, when the workpiece is properly positioned on the electrostatic chuck, the sensed capacitance may be higher than when the workpiece is not properly positioned. The varying level of current provided to the electrostatic chuck, in response to the application of an alternating current (AC) voltage, enables the capacitance of the electrostatic chuck to be monitored. More specifically, a small AC voltage is applied to the high-voltage clamping voltage via a first section of a transformer's primary, and changes in chuck capacitance are seen as amplitude variations in a small AC voltage measured on a second section of the primary. Consequently, the position of the workpiece may be monitored by monitoring the current provided to the electrostatic chuck.

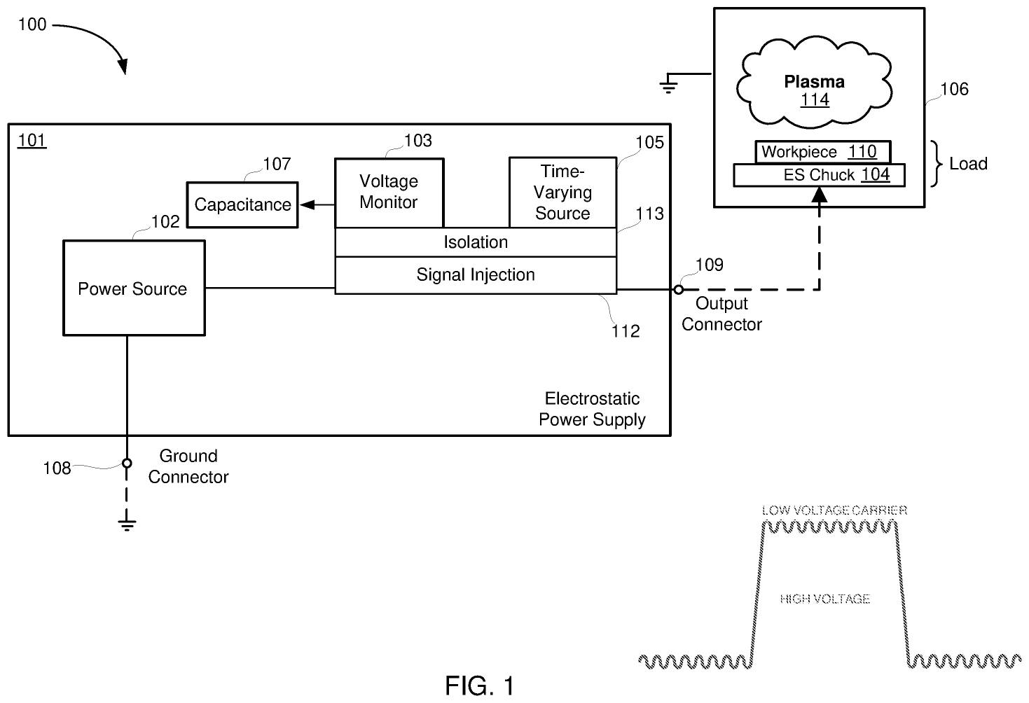

Referring first to FIG. 1, shown is an exemplary electrostatic power supply 100, which is one environment in which embodiments of capacitance sensing techniques may be utilized. As depicted, the electrostatic power supply 100 includes an electrostatic power supply 101 and an electrostatic chuck 104. As shown, the electrostatic chuck 104 is positioned within a plasma processing chamber 106, and a workpiece 110 is shown clamped to the electrostatic chuck 104.

In this exemplary application, the plasma processing chamber 106 may be realized by chambers of substantially conventional construction (e.g., comprising a vacuum enclosure which is evacuated by a pump or pumps (not shown)). And, as one of ordinary skill in the art will appreciate, the plasma excitation in the plasma processing chamber 106 may be achieved by any one of a variety of sources comprising, for example, a helicon type plasma source, which includes magnetic coil and antenna to ignite and sustain a plasma 114 in the reactor, and a gas inlet may be provided for introduction of a gas into the plasma processing chamber 106.

As depicted, the workpiece 110 to be treated (e.g., a semiconductor wafer), is supported at least in part by the electrostatic chuck 104, and power is applied to the electrostatic chuck 104 via one or more conductors (e.g., cables). For simplicity only a single conductor is shown coupled to the electrostatic chuck 104, but it should be recognized that aspects described herein are applicable to monopolar chucks and multipolar chucks. As an example, those of ordinary skill in the art will appreciate that six power lines and six corresponding capacitance monitors may be employed in connection with a hexapolar electrostatic chuck.

In general, the electrostatic power supply 101 is capable of applying a voltage that includes steady-state and time-varying components, such as DC and AC components. For example, the DC voltage may effectuate a DC clamping voltage at the electrostatic chuck 104 that draws the workpiece 110 to the electrostatic chuck 104 while the AC voltage may be utilized to monitor chuck capacitance, such as via a capacitance module 107 (e.g., to detect a position of the workpiece 110 relative to the electrostatic chuck 104).

As shown, the electrostatic power supply 101 may include a ground connector 108 configured to couple to ground, an node 109 (or node) configured to couple to a load (e.g., the combination of the electrostatic chuck 104 and the workpiece 110), a DC power source 102, and a time-varying source 105 (also referred to as a time-varying signal source or a time-varying power source) coupled between the DC power source 102 and the node 109. The time-varying sources disclosed herein, such as the time-varying source 105, may be realized, for example, by an AC source configured to provide an AC signal or a time-varying DC source configured to provide a time-varying DC signal, such as through utilizing ramp and step functions. As shown, the time-varying source 105 and the DC power source 102 are arranged in series in a conduction path between the ground connector 108 and the node 109 (also referred to as a node). The DC power source 102 is configured to apply a DC voltage onto the conduction path and the time-varying source 105 is configured to inject a time-varying signal (also referred to as a time-varying voltage signal or the capacitance sense signal), such as an AC signal, on to the conduction path. Also shown is a voltage monitor 103 that is configured to measure voltage in the conduction path, and a capacitance module 107 is coupled to the voltage monitor. The capacitance module 107 is configured to determine the capacitance based upon the measured voltage. Like the time-varying source 105, the voltage monitor 103 is galvanically isolated from the conduction path and signal injection 112, for instance, via a transformer.

In operation, the DC voltage applied by the DC power source 102 depicted in FIG. 1 (and throughout the figures of the present disclosure) may effectuate the DC clamping voltage when the electrostatic power supply 101 is coupled to the electrostatic chuck 104. For example, the DC power source 102 depicted in FIG. 1 (and throughout the figures of the present disclosure) may be capable of applying 1000 volts DC to effect clamping, but this voltage is exemplary only and may vary depending upon many factors. In many implementations, the DC power source 102 is realized by a switch-mode power supply, which can deliver high currents in a small form factor at high efficiency; thus, with less heat as compared to a linear amplifier. However, the disclosure is equally applicable to any type of power source 102, including DC sources and variable-output amplifiers to name two. The time-varying voltage injected by the time-varying source 105 may be 10 to 20 volts AC (peak-to-peak) at 1 kHz, but these voltages and frequency are exemplary only and may vary depending upon many factors.

As shown, the time-varying source 105 provides a time-varying signal to the conduction path via a signal injection component 112 that is separated from the time-varying source 105 by an isolation component 113. The signal injection component 112 is coupled to the conduction path with terminals that are galvanically isolated from other components of the electrostatic power supply 101.

In one implementation, the time-varying source 105 is as an AC power source, and a primary of a transformer is used to realize the isolation component 113, while a secondary of the transfer is used to realize the signal injection component 112. For example, a primary side of the transformer may be coupled to the power source 102 and the secondary side of the transformer may be disposed along the conduction path. The time-varying source 105 (e.g., AC power source) may be realized, for example without limitation, by a linear amplifier, a switch-mode amplifier (e.g., class D), or a waveform generator, to name three non-limiting examples. In one embodiment, the time-varying source 105 is a direct digital synthesizer to produce a DC representation of the AC signal and a digital-to-analog converter is used to convert the DC representation to the time-varying signal. In this implementation, the direct digital synthesizer and the digital-to-analog converter can receive power and control signals via galvanically-isolating coupling. In yet another implementation, the time-varying source 105 includes an oscillator to produce the time-varying signal (e.g., AC signal) wherein the oscillator receives power and control signals via a galvanically-isolated coupling.

The voltage monitor 103 depicted in FIG. 1 (and throughout the drawing figures of the present disclosure) may be realized by a voltage comparator or Zener diode, to name two non-limiting examples.

In some implementations, the capacitance monitoring aspects are implemented in a separate housing from the DC power source 102 of the electrostatic power supply 101. For example, an apparatus for measuring capacitance of a load may be implemented without the DC power source 102, and the apparatus for measuring capacitance may not have the functionality to clamp the workpiece 110 to the chuck 104.

In some implementations, the voltage measuring or capacitance monitoring aspects may comprise an analog-to-digital converter used to convert an analog representation of the measured voltage into a digital signal representation of the measured voltage. The capacitance monitoring aspects (e.g., the capacitance module 107) may process the measured analog voltage or a digital signal representation of the measured voltage, such as through filtering and synchronous detection, to determine the capacitance (e.g., via frequency and phase data extracted from the digital signal representation of the measured voltage). In a similar manner, measured current signals of the present disclosure may be converted into a digital signal representation and processed by the capacitance monitoring aspects to aid in determining capacitance.

The electrostatic power supply 101 can be used to measure capacitance of various capacitive loads, but to help with an appreciation of operation, will now be described in the context of measuring capacitance between an electrostatic chuck and a workpiece for the purpose of monitoring workpiece clamping. To detect a position of the workpiece 110 in the context of the electrostatic power supply 100, the relationship between capacitance and positions of workpiece may be empirically determined, and threshold capacitances may be established that are indicative of, for example, the workpiece 110 “in place” or the workpiece 110 “in clamp.” The threshold capacitance values may be stored in nonvolatile memory in connection with workpiece position data to enable a mapping between capacitance values and workpiece position. The workpiece position may be determined using the empirically obtained data in connection with the voltage measurements to obtain a capacitance seen at the electrostatic chuck 104. As those of ordinary skill in the art readily appreciate, capacitance of a load may be determined based upon the time-varying (e.g., AC) voltage and current as follows:

$$I ( t ) = C \frac{d V}{dt} .$$

Once the capacitance of the load (e.g., the combination of the electrostatic chuck 104 and the workpiece 110) is obtained, the position of the workpiece 110 may be obtained by reference to the stored data in nonvolatile memory.

As seen, the present disclosure generally relates to an electrostatic wafer clamping and sensing system. The system includes a power source such as, but not limited to, a high voltage DC power supply or variable output amplifier, an isolation component (e.g., a transformer), a time-varying source (or AC voltage source), and a voltage sensing circuit. The power source is configured to provide a high voltage clamping signal such as the DC signal at the lower right of FIG. 1. The transformer has a primary and a secondary, with the secondary coupled in series with the power source and an output or node configured for coupling to a capacitive load such as the electrostatic chuck of a plasma processing chamber.

Often, a filter, such as a low pass filter (e.g., an RCL filter), is located between the node and the capacitive load, which would preclude traditional capacitance sense signals from reaching the capacitive load. However, in this disclosure, the time-varying source is configured to operate at a frequency within a bandpass of a given filter (e.g., a low pass filter) of a plasma processing chamber. This is partly enabled by the primary of the transformer having two sides separated by a center tap (e.g., at ground or any reference voltage and in some cases referenced to the same voltage as the time-varying source). A first or input side of the primary is coupled to the time-varying source and the second or output side is coupled to the voltage sensing circuit (or amplitude modulation sensing circuit). The center tap provides signal separation between the time-varying source and the voltage sensing. In other words, the time-varying signal is coupled into (injected into) the secondary via the portion of the primary on the input side of the tap, and a time-varying sensed signal is coupled back into the primary on the output side of the tap and measured by the voltage sensing circuit. The tap prevents mixing of the injected and sensed signals on the primary, which allows a single transformer to perform both sourcing and sensing of the capacitive sense signal. While the time-varying source has a constant amplitude, the sensed signal has a varying peak-to-peak amplitude that responds to load capacitance (e.g., clamping state of an electrostatic chuck). Moreover, the position of the tap can be adjusted to tailor a gain of the sensed signal relative to the time-varying source for different applications (e.g., greater gain may be desired where a smaller load capacitance is seen). In other words, the number of turns on either side of the tap can be selected to achieve a desired gain between the time-varying source and the sensing section. For purposes of this disclosure, the tap is sometimes referred to as a center tap since it is arranged somewhere between the opposing ends of the primary-though the number of turns on either side of the tap can be selected to achieve a desired gain. Hence, the herein disclosed electrostatic power supply is capable of monitoring the position of a workpiece, such as a wafer, relative to an electrostatic chuck, even where a filter is arranged between the electrostatic power supply and the electrostatic chuck.

The system can be arranged external to the power source, or it can be part of the same housing. To this end, a capacitance sensing section (e.g., 206) will be described separate from the power source throughout this disclosure, though those of skill will appreciate that these descriptions and figures also apply to situations where the power source and capacitance sensing section share the same housing.

In some operational variations, the output of the primary can optionally be rectified to a direct current (DC) voltage for measurement. This can be achieved, for example, via a diode. The rectification of the primary's output allows for easier and more accurate measurement of the amplitude modulated capacitance sense signal, thereby further enhancing the control over the clamping state of the electrostatic chuck.

In some configurations, the input and output of the primary can include DC filters, in one instance implemented as capacitors. These DC filters can help to eliminate any DC components in the input and output signals of the primary, thereby ensuring that the amplitude modulated capacitance sense signal accurately reflects the clamping state of the electrostatic chuck.

To avoid DC saturation in the transformer, a bypass circuit can be implemented. For instance, in some configurations, a resistive device, such as a resistor, can be arranged in parallel with the secondary of the high-voltage transformer. The resistive device provides a low-impedance path for the DC of the combined signal to bypass the transformer, thereby preventing DC saturation of the transformer. In addition to the resistive device, a capacitive device, such as a capacitor, can be arranged in parallel with the resistive device and the secondary of the high-voltage transformer. This configuration provides a path for the time-varying (e.g., AC) component of the combined signal to bypass the transformer. The capacitive device can help to stabilize the AC portion of the combined signal, thereby enhancing the overall performance of the system.

The arrangement of the electrostatic wafer clamping and sensing system can vary depending on the specific implementation. In some cases, the system is arranged external to the power source. This configuration allows for the system to be added as a modular component to existing off-the-shelf power supplies or amplifiers. This can be particularly beneficial in scenarios where there is a desire to add capacitance sensing capabilities to existing equipment without the need for extensive modifications or custom-built components. In other cases, the system is part of the power source. This configuration allows for a more integrated solution, where the system is built directly into the power supply or amplifier. This can provide advantages in terms of space efficiency and system integration, as the system components are primarily contained within a single apparatus. This can also simplify the system design and reduce the number of external connections, potentially enhancing the reliability and robustness of the system.

Regardless of the specific arrangement, the system is configured to provide a high voltage clamping signal and a low frequency capacitance sensing AC signal. These signals are combined and passed to a load, such as an electrostatic chuck, allowing for simultaneous clamping of the workpiece and monitoring of the clamping state. The use of a tapped connection arranged between opposing ends of the primary allows signal separation between the input and output segments of the primary. This, along with use of a capacitance sensing signal having a frequency tailored to a filter between the electrostatic power supply and the capacitive load, allows the system to perform both clamping and monitor workpiece clamping despite the existence of a filter upstream from the electrostatic chuck or other load.

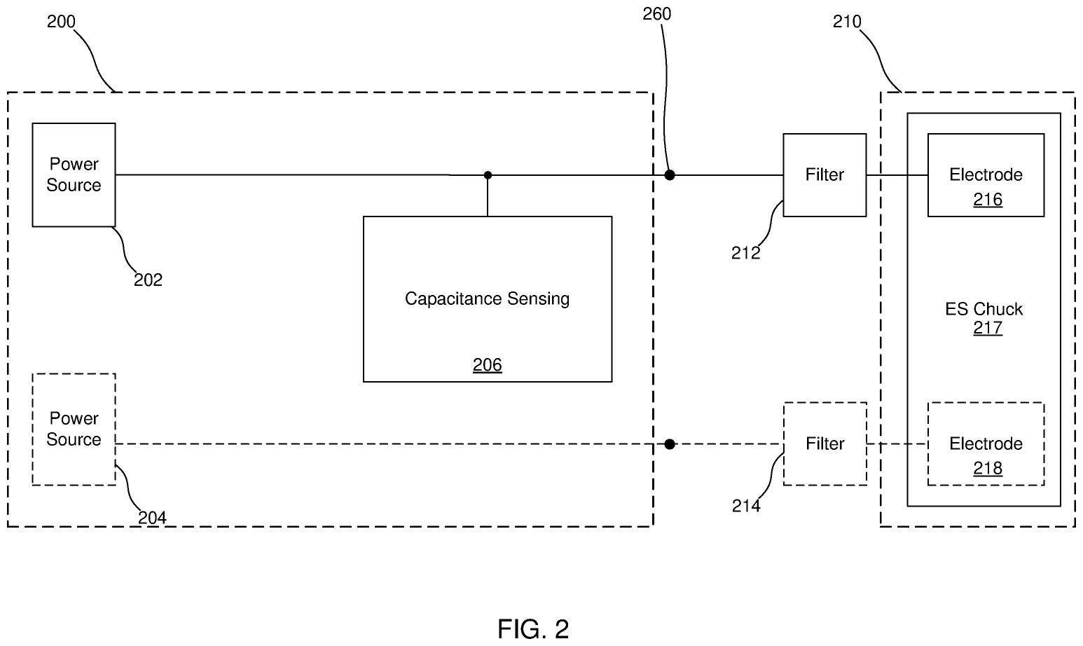

Referring to FIG. 2, the electrostatic power supply 200 includes a power source 202, a capacitance sensing section 206, and provides an output to a node 260 that is configured for coupling to a capacitive load 210 via a filter 212. The capacitive load 210 includes an electrostatic chuck 217, having an electrode 216. The output to node 260 is coupled to the electrode 216 via the filter 212, which may take the form of a low pass filter, high pass filter, or any other type of filter, and may be embodied in an RLC circuit, for example. The power sources 202 and 204 may be capable of applying 1000 or 2000 volts DC, but these voltages are exemplary only and may vary depending upon many factors. In many implementations, the power sources 202 and 204 are realized by switch-mode power supplies, which can deliver high currents in a small form factor at high efficiency; thus, with less heat as compared to a linear amplifier. Optionally, the electrostatic chuck 217 can be a multi-segment chuck having two or more channels and two or more corresponding electrodes. The illustrated embodiment shows a second channel, a second electrode 218 (or second chuck segment), and a second filter 214. The electrostatic power supply 200 includes a corresponding second power source 204. In a multi-segmented configuration, the electrodes 216, 218 are configured to jointly or independently apply an electrostatic clamping force to a substrate (e.g., a semiconductor wafer) when energized with a DC voltage or current. However, one of skill in the art will appreciate that FIG. 2 is applicable to any multi-segmented electrostatic chuck, such as those having six segments or channels. The capacitance sensing section 206 is coupled to the first channel, but not the second channel, though in some instances, a second capacitance sensing section on the second channel can be implemented. The electrostatic chuck 217, via the one or more electrodes, generates an electrostatic force that clamps the workpiece (not shown), such as a wafer, to the surface of the electrostatic chuck 217. The clamping force is adapted to the substrate, ensuring a secure hold during various workpiece processes.

In some cases, the power source 202 (and optionally 204) is configured to turn on and off in response to the clamping and declamping of substrates. This operational variation allows for dynamic control of the clamping force applied to the workpiece. When a substrate is to be clamped, the power source 202 is turned on, generating the high voltage clamping signal that energizes the electrode(s) 216 (218) of the electrostatic chuck 217. Conversely, when a substrate is to be declamped, such as for moving the substrate to a next chamber in a processing line, the power source 202 is turned off, ceasing the generation of the high voltage clamping signal and allowing the workpiece to be released from the electrostatic chuck 217. This operational flexibility enhances the system's 200 adaptability to different workpiece processes and conditions. The power source(s) 202 (204) can provide DC or AC power and some non-limiting examples include a high voltage DC power supply and a variable output amplifier.

The filter 212, such as an RLC filter, can disturb or block known capacitance sensing signals. Accordingly, the capacitance sensing section 206 uses a low amplitude time-varying capacitance sensing signal injected into the high voltage from the power source 202 to interrogate the electrode 216 through the filter 212, and operates at a bandpass of the filter 212. For instance, many filters 212 in the plasma processing context, have a low frequency bandpass, so the capacitance sensing section 206 may generate a time-varying signal that is low frequency or tailored to the bandpass of the filter 212 (e.g., 5-50 Hz). The time-varying signal may also be adjustable so that the electrostatic power supply 200 can be tailored for different capacitive loads 210. In particular, the time-varying signal can be adjusted anytime that the electrostatic power supply 200 is coupled to a new/different processing chamber, as this typically involves dealing with a different filter 212. For instance, the time-varying signal may be set to 10 Hz for a first electrostatic chuck and then coupled to a new electrostatic chuck and changed to 20 Hz. In these ways, the capacitance sensing section 206, and its electrostatic power supply 200 can monitor the position of a workpiece via capacitance, or the capacitance of any capacitive load, even when a filter is arranged between the electrostatic power supply and a capacitive load, such as an electrostatic chuck.

Although only one of the two illustrated channels includes a capacitance sensing 206, in other embodiments, both channels can be monitored via a separate capacitance sensing.

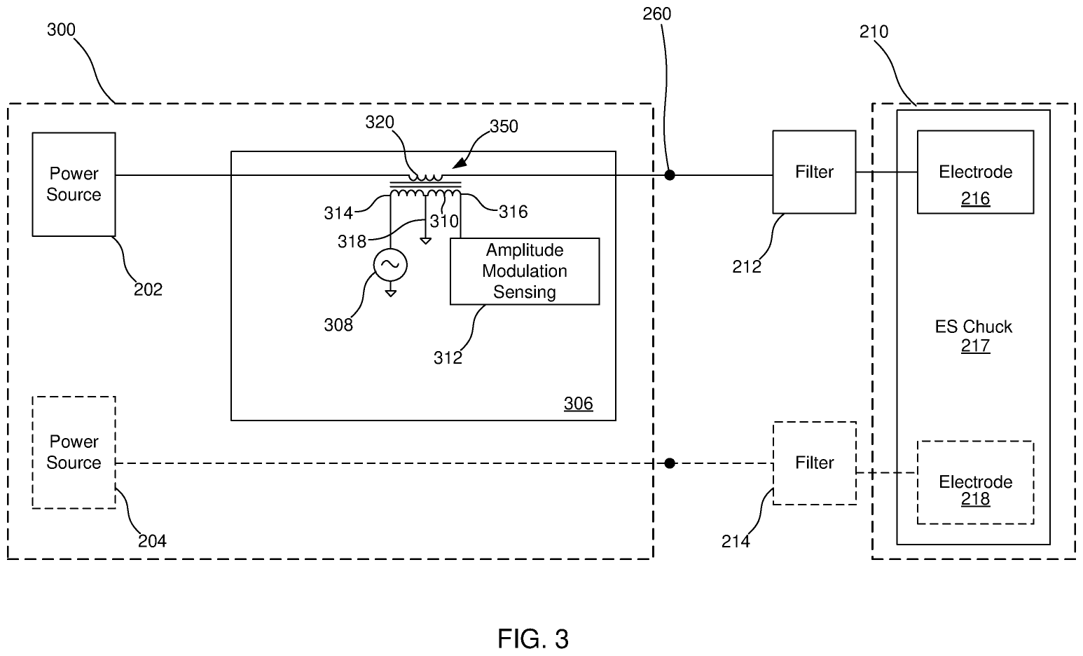

FIG. 3 provides additional details of an embodiment of the capacitance sensing seen in FIG. 2. The capacitance sensing section 306 includes a transformer 350 comprising a primary 310 and a secondary 320. The secondary 320 is coupled to an output of the power source 202 and to a node 260 (e.g., in series with the power source 202 and the node 260). A time-varying source 308 is coupled to a first side (or input) of the primary 310 and an amplitude modulation sensing section 312 (or voltage sensing section in some embodiments) is coupled to a second side (or output) of the primary 310. The time-varying source 308 generates a time-varying voltage that is injected into the clamping voltage from the power source 202, forming a combined signal in the secondary 320 that is provided to the node 260 and on to the capacitive load 210. The combination of these signals allows for simultaneous clamping of the workpiece and monitoring of the clamping state. The high voltage clamping signal provides the electrostatic force for clamping the workpiece, while the low frequency capacitance sensing time-varying signal provides a means for monitoring the clamping state based on the sensed capacitance. Changes in capacitance at the electrostatic chuck 217 will not be reflected in changes to the high voltage DC offset of the combined signal (the portion coming from the power source 202), but will be seen as amplitude modulations of the small time-varying signal detected at the amplitude modulation sensing section 312 via the second portion of the primary 310. In other words, the amplitude modulation sensing section 312 detects amplitude modulation in the injected signal.

The primary 310 further includes a tap 318 such as a grounded tap, though any reference voltage could be used, not just ground. In some cases, the time-varying source 308 and the tap 318 can include a common, such as ground or any other reference voltage (the illustrated embodiment shows a common ground). The time varying source 308 operates at a frequency within the bandpass of the filter 212. This operation within the bandpass of the filter 212 allows a substantial portion of the capacitance sense signal to reach the electrostatic chuck, thereby enabling effective monitoring of the position of the workpiece. In some cases, the time-varying source 308 is configured to operate at a frequency of 5 to 50 Hz where a low pass filter is encountered. Operating at a frequency tailored to the filter in question enhances the ability of the capacitance sense signal to pass through the filter 212 and reach the electrostatic chuck 217. Furthermore, since the electrostatic power supply 300 may be implemented with different loads and thus different filters, it is advantageous to have a source of the capacitance sense signal that can be modified (e.g., increase or decrease frequency) to accommodate the different filters experienced without significant changing of components within the electrostatic power supply 300. This flexibility in adjusting the amplitude and/or frequency of the input of the primary enhances the adaptability of the system to different workpiece processes, conditions, and different chambers. Thus, although the time-varying source 308 can operate at a fixed frequency and amplitude, the frequency may alternatively be adjustable to account for different filters 212 that may be seen in different applications or when used with different electrostatic chucks 217. For instance, where the filter 212 has a low passband, the time-varying source 308 may have a low frequency such as 5-50 Hz. If the electrostatic power supply 300 is coupled to a different capacitive load 210, a different filter 212 will likely be encountered, and the low frequency of the time-varying source 308 can be adjusted to match the new filter.

The tap 318 is arranged between the primary's 310 input 314 and output 316 and splits the primary into an input section and an output (or sensing) section (or first and second sides, respectively) with the time-varying source 308 coupled to the input section and the amplitude modulation sensing section 312 coupled to the output section. The tap 318 provides signal separation between the time-varying voltage from the time-varying source 308 on the first side of the primary and the amplitude modulated or sensed signal (or time-varying amplitude) on the second side of the primary 310.

This configuration allows for the combination of the high clamping voltage and a low frequency time-varying signal (e.g., a capacitance sensing AC signal) from the time-varying source 308, the combined signal is then passed to a load 210 such as an electrostatic chuck 217. The combination of these signals allows for simultaneous clamping of the workpiece and monitoring of the clamping state. The high voltage clamping signal provides the electrostatic force for clamping the workpiece, while the low frequency capacitance sensing AC signal provides a means for monitoring the clamping state based on the sensed capacitance. The transformer galvanically isolates the capacitance sensing circuitry from the high-voltage conduction path thereby allowing less complex and less costly components to be used on the sensing side. The time-varying voltage is coupled into (injected into) the secondary 320 via the first side of the primary 310, and a time-varying sensed signal is coupled back into the primary 310 on the second side of the primary 310 and measured by the amplitude modulation sensing section 312. The tap 318 prevents mixing of the injected and sensed signals on the primary 310, which allows a single transformer 350 to perform both sourcing and sensing of the capacitive sense signal. The tap 318 also enables the sensed signal to mirror the phase and frequency of the injected signal, though the amplitude will vary depending on sensed load capacitance. While the time-varying source 308 has a steady amplitude, the sensed signal has a varying peak-to-peak amplitude that responds to load capacitance (e.g., clamping state of an electrostatic chuck 217), and hence sensing is said to be performed via amplitude modulation. Said another way, the amplitude on the second side of the tap 318 is proportional to a capacitance at the node 260.

The tap 318 can be a center tap, though it can also be positioned anywhere along the primary and even moved in some embodiments, to allow tailored gain and even modifiable gain (the gain being between the injected signal and the sensed signal). For instance, greater gain may be desired where a smaller load capacitance is seen. In some embodiments, the tap 318 can be located during production and then remains fixed in the field. In other embodiments, there may be an option to field adjust the tap 318 location.

The transformer 350 galvanically isolates the amplitude modulation sensing section 312 from the high-voltage conduction path thereby allowing less complex and less costly components to be used on the sensing side (primary side of the transformer 350).

In some instances, the secondary 320 has fewer turns than a number of turns in the primary 310. This configuration can be advantageous in situations where a reduction in the injected voltage at the secondary 320, as compared to the time-varying signal on the first side of the primary 310, is desired. By having fewer turns in the secondary 320, the transformer 350 can effectively step down the voltage level of the injected signal, allowing for more precise control over the capacitance sensing signal.

In some cases, the secondary 320 is a single conductor passing through a toroidal primary 310. This configuration can be beneficial in scenarios where space constraints are a concern, as a single conductor secondary can be more compact than a multi-turn secondary. Furthermore, a toroidal primary 310 can provide improved magnetic field containment, reducing the likelihood of interference with other components of the system.

In some configurations, a multi-segmented electrostatic chuck is implemented, each segment having a different power source, though a single capacitance sensing system can be used. On the other hand, multiple capacitance sensing systems can be implemented and can operate at slightly different amplitude and/or frequency in order to avoid AC signal loss in the respective filter. These configurations allow for precise control over the clamping force applied to different segments of the workpiece, thereby enhancing the overall performance of the electrostatic wafer clamping and sensing system. The illustrated embodiment includes a single channel, a single power source 202, a single capacitance sensing section 306, and a single electrode 216 and filter 212. However, this embodiment is optionally shown with a second channel and a second set of corresponding components, though only a single capacitance sensing section.

The amplitude modulation sensing section 312 looks at voltage, though current amplitude modulation can alternatively be monitored. This amplitude modulation sensing section 312 is coupled to an opposing end of the primary 310 of the transformer 350 (or an output 316 of the primary 310). The amplitude modulation sensing section 312 detects amplitude modulation in the injected signal on the secondary 320 via coupling back into the second section of the primary 310. This signal is indicative of the clamping state of the electrostatic chuck 217, and allows for real-time monitoring of the clamping state, thereby enhancing the overall control over the workpiece processes.

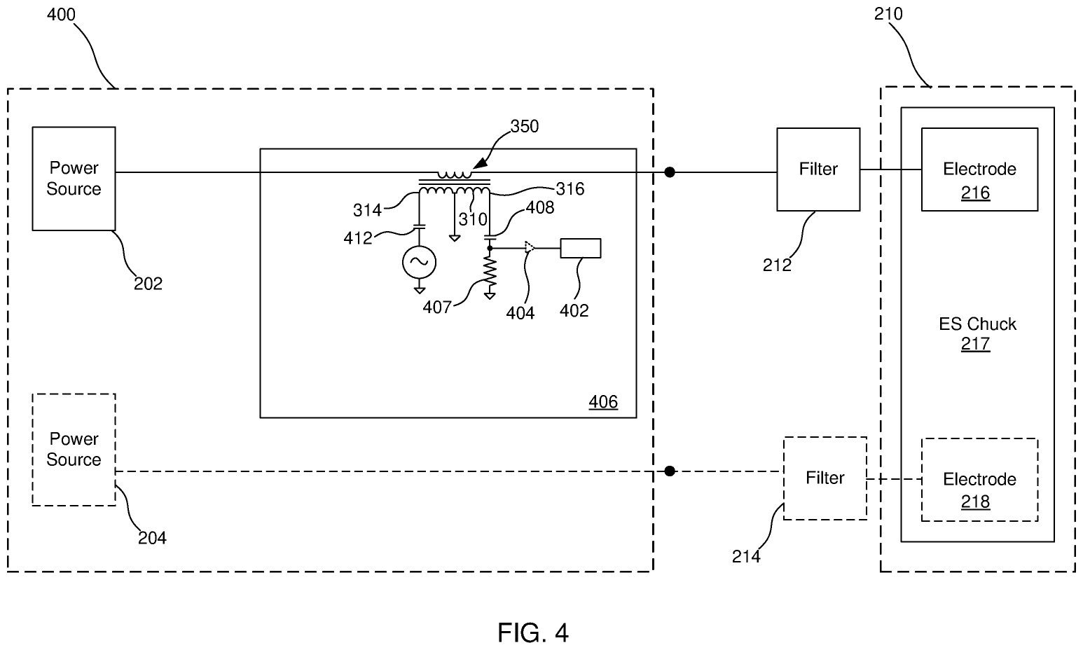

FIG. 4 presents additional details of the amplitude modulation sensing circuit of FIG. 3. In this embodiment, a resistive device 407 at the primary's output 316 provides a ground referenced voltage measurement. The resistive device 407 is configured such that the amplitude modulated capacitance sense signal has a voltage equal to the voltage drop across the resistive device 407. This configuration allows for precise measurement of the amplitude modulated capacitance sense signal, thereby enhancing the accuracy of the clamping state monitoring. The amplitude modulation sensing circuit can further include a monitor 402 (e.g., a voltage monitor) arranged to measure voltage across the resistive device 407. In some operational variations, the output of the primary 310 can optionally be rectified to a direct current (DC) voltage for measurement. This can be achieved, for example, via an optional diode 404. The rectification of the primary's output 316 allows for easier and more accurate measurement of the amplitude modulated capacitance sense signal, thereby further enhancing the control over the clamping state of the electrostatic chuck 217.

In some embodiments, a capacitive device 408 (e.g., a capacitor) can be arranged between the primary's output 316 and the resistive device 407, and the amplitude modulation can be sensed by the monitor 402 from between the capacitive device 408 and the resistive device 407.

In some configurations, the input 314 and output 316 of the primary can include DC filters, in one instance implemented as capacitors. These DC filters (e.g., 412 and 408) can help to eliminate any DC components in the input and output signals of the primary 310, thereby ensuring that the amplitude modulated capacitance sense signal measured by the monitor 402 accurately reflects the clamping state of the electrostatic chuck 217.

In some configurations, a multi-segmented electrostatic chuck is implemented, each segment having a different power source, though a single capacitance sensing system can be used. On the other hand, multiple capacitance sensing systems can be implemented and can operate at slightly different amplitude and/or frequency in order to avoid AC signal loss in the respective filter. These configurations allow for precise control over the clamping force applied to different segments of the workpiece, thereby enhancing the overall performance of the electrostatic wafer clamping and sensing system. The illustrated embodiment includes a single channel, a single power source 202, a single capacitance sensing section 406, and a single electrode 216 and filter 212. However, this embodiment is optionally shown with a second channel and a second set of corresponding components, though only a single capacitance sensing section.

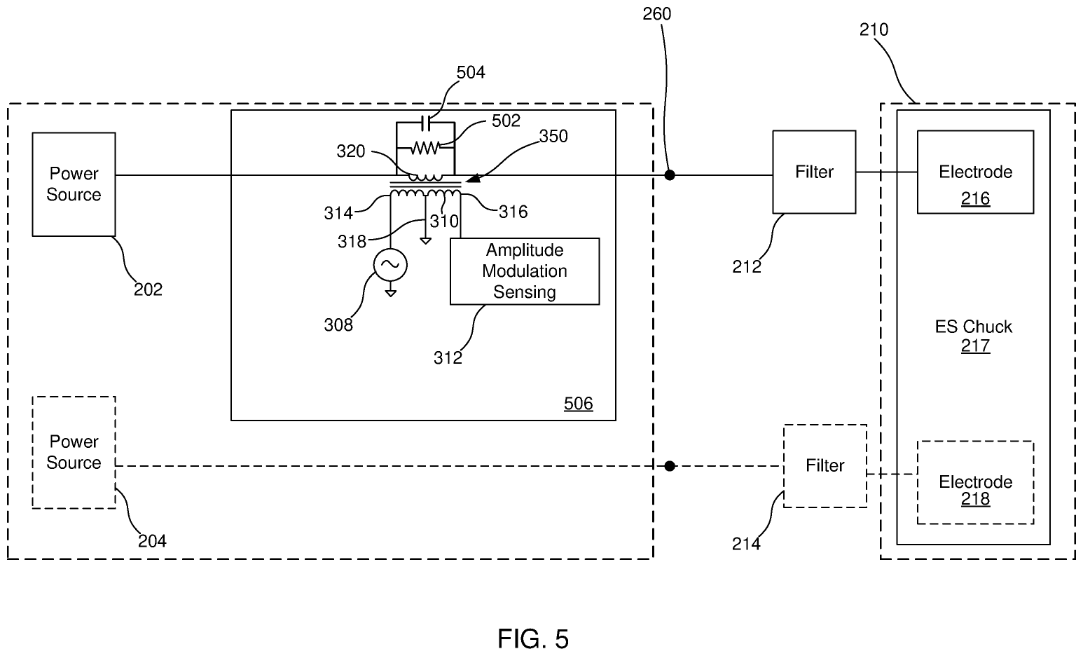

FIG. 5 presents another electrostatic power supply having a bypass circuit to the transformer configured to avoid DC saturation in the transformer. As shown, a resistive device 502, such as a resistor, can be arranged in parallel with the secondary 320 of the high-voltage transformer 350. The resistive device 502 provides a low-impedance path for the clamping voltage to bypass the transformer 350, thereby preventing DC saturation of the transformer 350. In addition to the resistive device 502, a capacitive device 504, such as a capacitor, can be arranged in parallel with the resistive device 502 and in parallel with the secondary 320 of the high-voltage transformer 350. This configuration provides a path for the time-varying (e.g., AC) component of the combined signal to bypass the transformer 350 on route to the node 260. The capacitive device 504 can help to stabilize the time-varying portion of the combined signal, thereby enhancing the overall performance of the capacitance sensing section 506.

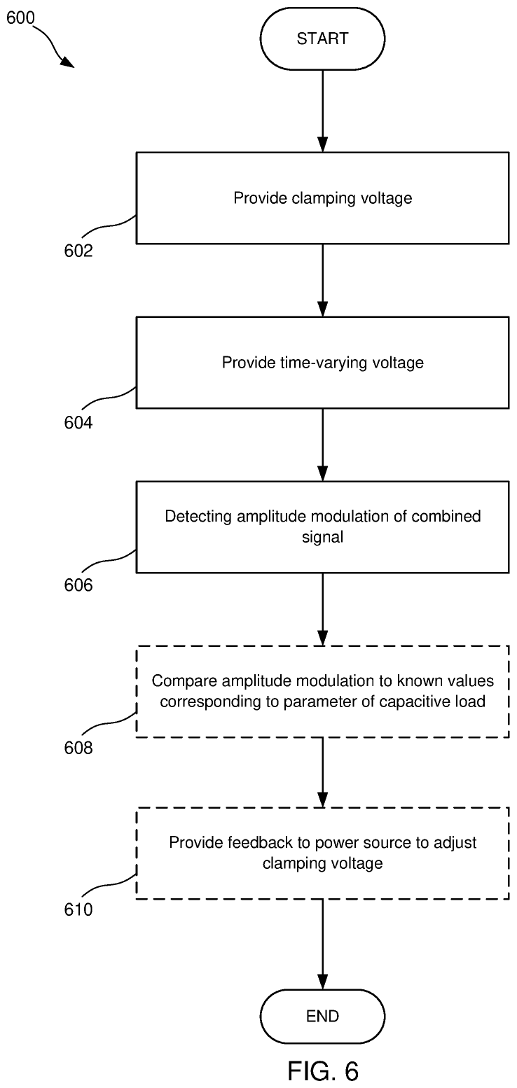

FIG. 6 illustrates an embodiment of a method for capacitance sensing of a capacitive load where a filter is arranged between an electrostatic power supply and the capacitive load. The method 600 includes providing a clamping voltage (e.g., 1000-2000 V DC pulsed to effectuate clamping and declamping) (Block 602), providing a time-varying voltage (the capacitance sensing signal), typically having a much lower amplitude than the clamping voltage (Block 604) to forma a combined signal, and detecting amplitude modulation of a combined signal that results from the time-varying voltage being inductively coupled to the clamping voltage (Block 606). Optionally, the amplitude modulation can be compared to known values to assess a parameter of the capacitive load (e.g., wafer clamping quality) (Block 608), and optionally used to provide feedback to a power source to adjust the clamping voltage (Block 610).

The time-varying voltage is injected into the clamping voltage via a first segment of a primary of a transformer (e.g., 31) and a secondary of the transformer, to form a combined signal. The combined signal is passed to a node (e.g., 260) configured for coupling to a capacitive load (e.g., 210) having a filter (e.g., 212) arranged between the node and the capacitive load. The filter can have components that tend to block traditional capacitance sensing signals. However, the time-varying voltage can be configured to match a bandpass of the filter. The combined signal may see amplitude modulations of the time-varying component thereof, and these amplitude modulations are inductively coupled back through the transformer to a second segment of the primary and measured via an amplitude modulation sensing section (e.g., 312). In an embodiment, the measured amplitude modulations can be compared to one or more empirically derived thresholds to ascertain whether clamping has been effectuated in an electrostatic chuck, and where multiple thresholds are used, a quality of clamping can also be determined. In some instances, this determination can be used to provide feedback to a power source to adjust the clamping voltage and thereby optimize clamping quality.

In some configurations, a multi-segmented electrostatic chuck is implemented, each segment having a different power source, though a single capacitance sensing system can be used. On the other hand, multiple capacitance sensing systems can be implemented and can operate at slightly different amplitude and/or frequency in order to avoid AC signal loss in the respective filter. These configurations allow for precise control over the clamping force applied to different segments of the workpiece, thereby enhancing the overall performance of the electrostatic wafer clamping and sensing system. The illustrated embodiment includes a single channel, a single power source 202, a single capacitance sensing section 506, and a single electrode 216 and filter 212. However, this embodiment is optionally shown with a second channel and a second set of corresponding components, though only a single capacitance sensing section.

Although the herein disclosed capacitance sensing system has been described and shown primarily as applied to a plasma processing system, it also has application in other industries, such as, but not limited to, the automotive industry and aerospace. In some embodiments, the capacitance sensing system can be applied to monitoring and controlling the position of various components, especially where fine accuracy is needed, such as in controlling the position of robotic arms and cutters and 3D printing heads. As another example, it can be used in the electrostatic painting process where the position of the car body parts is of utmost relevance. The system can ensure that the parts are properly positioned before the painting process begins, thereby improving the quality of the paint job and reducing waste.

In the manufacturing industry, the capacitance sensing system can be used in automated assembly lines. The system can monitor the position of the workpieces and ensure they are correctly placed before the assembly process begins. This can help to prevent errors and improve the efficiency of the assembly line.

The capacitance sensing system can be used in the medical field for monitoring the position of medical devices or components. For example, it can be used in the positioning of a patient during a medical imaging procedure such as an MRI or CT scan. The system can ensure that the patient is properly positioned before the imaging process begins, thereby improving the quality of the images and reducing the risk of errors.

In robotics, the capacitance sensing system can be used to monitor the position of robotic arms or other components. This can help to ensure that the robotic components are properly positioned before performing a task, thereby improving the accuracy and efficiency of the robotic system.

The capacitance sensing system can be used in the production of consumer electronics such as smartphones, tablets, and laptops. The system can monitor the position of various components during the assembly process, ensuring they are correctly placed before the assembly process continues. This can help to prevent errors and improve the quality of the final product.

As shown above, the applications of the herein disclosed capacitance sensing system are myriad.

Although the capacitance sensing has been shown primarily on a single channel in these figures, in other embodiments, more than one channel could include capacitance sensing (e.g., two of two channels). Similarly, while each channel has been shown with a filter, in some embodiments, less than all channels may include a filter (e.g., one of two channels).

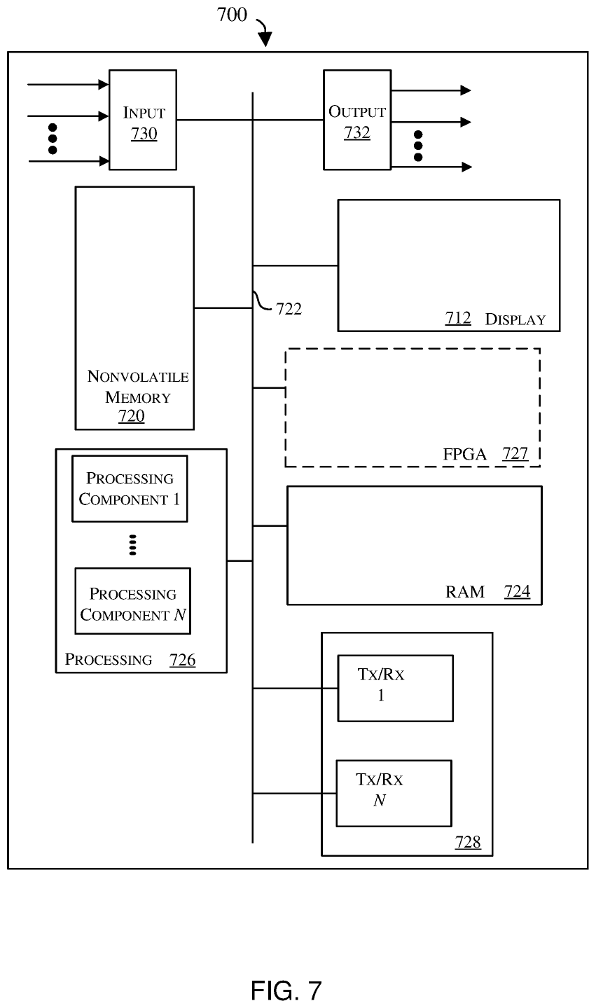

As described above, the functions and methods described in connection with the embodiments disclosed herein may be effectuated utilizing hardware, in processor executable instructions encoded in non-transitory, tangible computer-readable storage medium, or as a combination of the two. Referring to FIG. 7 for example, shown is a block diagram depicting physical components that may be utilized to realize one or more aspects of the capacitance sensing technologies disclosed herein. Moreover, multiple instances of the computing device depicted in FIG. 7 may be implemented in the systems described herein. As shown, in this embodiment a display 712 and nonvolatile memory 720 are coupled to a bus 722 that is also coupled to random access memory (“RAM”) 724, a processing portion (which includes N processing components) 726, a field programmable gate array (FPGA) 727, and a transceiver component 728 that includes N transceivers. Although the components depicted in FIG. 7 represent physical components, FIG. 7 is not intended to be a detailed hardware diagram; thus, many of the components depicted in FIG. 7 may be realized by common constructs or distributed among additional physical components. Moreover, it is contemplated that other existing and yet-to-be developed physical components and architectures may be utilized to implement the functional components described with reference to FIG. 7.

The display 712 generally operates to provide a user interface for a user, and in several implementations, the display 712 is realized by a touchscreen display. For example, display 712 can be implemented as a part of the voltage monitors and capacitance sensing modules to enable a user to change settings of the systems disclosed herein and/or receive operational feedback about the systems comprising workpiece (e.g., wafer) position information and capacitance information.

In general, the nonvolatile memory 720 is non-transitory memory that functions to store (e.g., persistently store) data and machine readable (e.g., processor executable) code (comprising executable code that is associated with effectuating the methods described herein). In some embodiments, for example, the nonvolatile memory 720 includes bootloader code, operating system code, file system code, and non-transitory processor-executable code to facilitate the execution of the methods described herein. The nonvolatile memory 720 may also be used to store empirically obtained data that relates workpiece position to capacitance data.

In many implementations, the nonvolatile memory 720 is realized by flash memory (e.g., NAND or ONENAND memory), but it is contemplated that other memory types may also be utilized. Although it may be possible to execute the code from the nonvolatile memory 720, the executable code in the nonvolatile memory is typically loaded into RAM 724 and executed by one or more of the N processing components in the processing portion 726.

In operation, the N processing components in connection with RAM 724 may generally operate to execute the instructions stored in nonvolatile memory 720 to realize the functionality of one or more components and modules disclosed herein. As one of ordinary skill in the art will appreciate, the processing portion 726 may include a video processor, digital signal processor (DSP), graphics processing unit (GPU), and other processing components. In digital implementations, a DSP may be used to effectuate aspects of the time-varying signal injection.

In addition, or in the alternative, the field programmable gate array (FPGA) 727 may be configured to effectuate one or more aspects of the functions and methodologies described herein. For example, non-transitory FPGA-configuration-instructions may be persistently stored in nonvolatile memory 720 and accessed by the FPGA 727 (e.g., during boot up) to configure the FPGA 727 to effectuate the functions described herein.

The input component may operate to receive signals (e.g., from the amplitude modulation sensing) that are indicative of the amplitude modulated capacitance sensing signal. And the output component generally operates to provide one or more analog or digital signals to effectuate an operational aspect of components described herein. For example, the output portion may transmit output signal(s) indicative of voltage modulation levels corresponding to workpiece position or feedback signals to adjust the power source's clamping voltage in response to imprecise clamping situations.

The depicted transceiver component 728 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A system, comprising:
a power source configured to provide a voltage to a node;
a transformer having a primary and a secondary, the secondary coupled to the power source and the node, the primary comprising a center tap;
a time-varying source coupled to the primary of the transformer on a first side of the center tap; and
a sensing circuit coupled to the primary of the transformer on a second side of the center tap, and configured to measure a time-varying amplitude on the second side of the center tap.

2. The system of claim 1, wherein an amplitude and/or frequency of the time-varying source is configured to match a bandpass of a filter arranged between the node and a capacitive load.

3. The system of claim 2, wherein the time-varying source operates at a frequency of 5 Hz to 50 Hz.

4. The system of claim 1, wherein the center tap and the time-varying source are referenced to a common voltage.

5. The system of claim 1, wherein the secondary of the transformer has fewer turns than a number of turns in the primary and the secondary coupled in series to the power source and the node.

6. The system of claim 1, further comprising a resistive device at an output of the primary to provide a ground referenced voltage measurement.

7. The system of claim 1, wherein a number of turns of the primary on both sides of the center tap is selected to achieve a desired gain between the time-varying source and the sensing circuit.

8. The system of claim 1, wherein the amplitude on the second side of the center tap is proportional to a capacitance at the node.

9. An apparatus, comprising:
a power source configured to provide a voltage;
a transformer comprising a primary and a secondary, the secondary coupled to an output of the power source;
a time-varying source coupled to the primary of the transformer and configured to inject a time-varying signal onto a conduction path between the power source and a node; and
a monitor configured to measure time-varying amplitude in the conduction path via a portion of the primary.

10. The apparatus of claim 9, wherein a center tap separates the portion of the primary coupled to the monitor from the portion of the primary coupled to the time-varying source.

11. The apparatus of claim 10, wherein a frequency of the time-varying source is configured to correspond with a passband of a filter arranged between the node and a capacitive load.

12. The apparatus of claim 11, wherein the frequency of the time-varying source is between 5 Hz and 50 Hz.

13. The apparatus of claim 9, wherein the secondary of the transformer has fewer turns than a number of turns in the primary.

14. The apparatus of claim 9, wherein the time-varying source is configured to provide a constant amplitude, while an amplitude at the monitor varies in response to a capacitance seen at the node.

15. The apparatus of claim 14, wherein the monitor provides feedback configured to adjust the power source in response to the capacitance seen at the node.

16. A non-transitory, tangible computer-readable storage medium storing instructions that, when executed by a processor, cause a system to perform operations, comprising:
providing a clamping voltage;
providing a time-varying voltage; and
detecting amplitude of a combined signal that results from the time-varying voltage being inductively coupled to the clamping voltage.

17. The non-transitory, tangible computer-readable storage medium of claim 16, wherein the time-varying voltage is injected into the clamping voltage via a transformer having a primary, a secondary, and a center tap in the primary, the time-varying voltage configured to be provided to a first side of the center tap.

18. The non-transitory, tangible computer-readable storage medium of claim 17, wherein the modulation is configured to be coupled into and detected at a second side of the center tap.

19. The non-transitory, tangible computer-readable storage medium of claim 18, further comprising selecting a frequency of the time-varying voltage to correspond to a bandpass of a filter between the transformer and a capacitive load.

20. The non-transitory, tangible computer-readable storage medium of claim 16, further comprising comparing the modulation to one or more thresholds to ascertain a clamping state of a workpiece relative to an electrostatic chuck.
